(19) United States
(12) Patent Application Publication
(10) Pub. No.: US 2020/0305291 A1
(43) Pub. Date: Sep. 24, 2020

(54) DISPLAY MODULE OF DISPLAY DEVICE

(71) Applicants: HONG FU TAI PRECISION ELECTRONS (YANTAI) CO., LTD., Yantai (CN); HON HAI PRECISION INDUSTRY CO., LTD., New Taipei (TW)

(72) Inventors: HUNG-NAN TAI, New Taipei (TW); JING-XIAO YUAN, Yantai (CN); GUO-DONG WU, Yantai (CN)

(21) Appl. No.: 16/419,647

(22) Filed: May 22, 2019

(30) Foreign Application Priority Data
Mar. 19, 2019 (CN) 201910207997.0

(51) Int. Cl. H05K 5/00; G02F 1/1333; G06F 1/16

(52) U.S. Cl. CPC H05K 5/0017; G06F 1/1601; G02F 1/133308

(57) ABSTRACT

A display module includes a display panel, an optical film set, a backplane, at least two first bonding members bonding the display panel, the optical film set, and the backplane together, and a second bonding member. The optical film set is stacked between the display panel and the backplane. The optical film set includes a first adhering surface facing the display panel and a second adhering surface facing the backplane. The first bonding members are made of light-transmitting material. One first bonding member is disposed between the display panel and the optical film set. A second first bonding member is disposed between the optical film set and the backplane. The second bonding member is made of light non-transmitting material and is disposed on an outer side of the optical film set.

### FIELD

The subject matter herein generally relates to display devices, and more particularly to a display device having a borderless display module.

### BACKGROUND

A liquid crystal display (LCD) is generally used in flat, thin display devices. Currently, a bezel of the LCD limits a full-screen potential of the LCD.

### BRIEF DESCRIPTION OF THE DRAWINGS

Implementations of the present disclosure will now be described, by way of embodiments, with reference to the attached figures.

FIG. 1 is an assembled, isometric view of an embodiment of a display device.

FIG. 2 is a cross-sectional view of a first embodiment of a display module of the display device in FIG. 1.

FIG. 3 is a cross-sectional view of a second embodiment of a display module of the display device in FIG. 1.

FIG. 4 is a cross-sectional view of a third embodiment of a display module of the display device in FIG. 1.

FIG. 5 is a cross-sectional view of a fourth embodiment of a display module of the display device in FIG. 1.

FIG. 6 is a cross-sectional view of a fifth embodiment of a display module of the display device in FIG. 1.

FIG. 7 is a cross-sectional view of a sixth embodiment of a display module of the display device in FIG. 1.

### DETAILED DESCRIPTION

It will be appreciated that for simplicity and clarity of illustration, where appropriate, reference numerals have been repeated among the different figures to indicate corresponding or analogous elements. Additionally, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

Several definitions that apply throughout this disclosure will now be presented.

The term “substantially” is defined to be essentially conforming to the particular dimension, shape, or other word that “substantially” modifies, such that the component need not be exact. For example, “substantially cylindrical” means that the object resembles a cylinder, but can have one or more deviations from a true cylinder. The term “comprising” means “including, but not necessarily limited to”; it specifically indicates open-ended inclusion or membership in a so-described combination, group, series and the like.

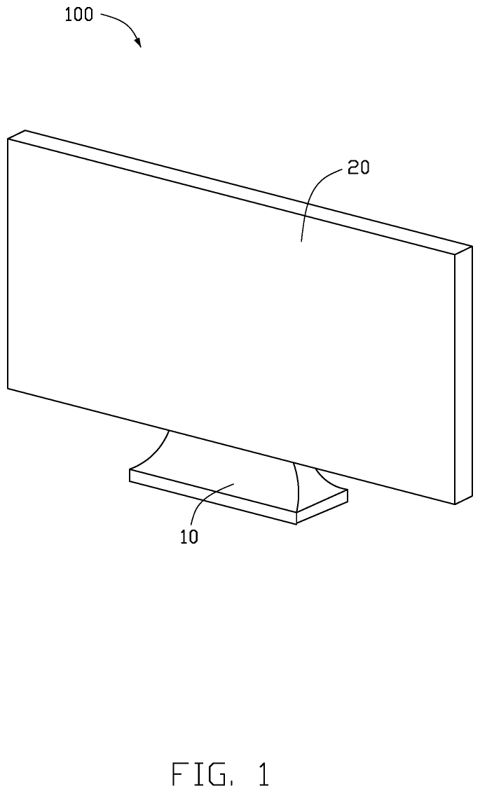

FIG. 1 shows an embodiment of a display device 100 including a support stand 10 and a display module 20. The display module 20 is mounted on the support stand 10. The display device 100 may be, but is not limited to, a television, a display monitor, a billboard, or the like.

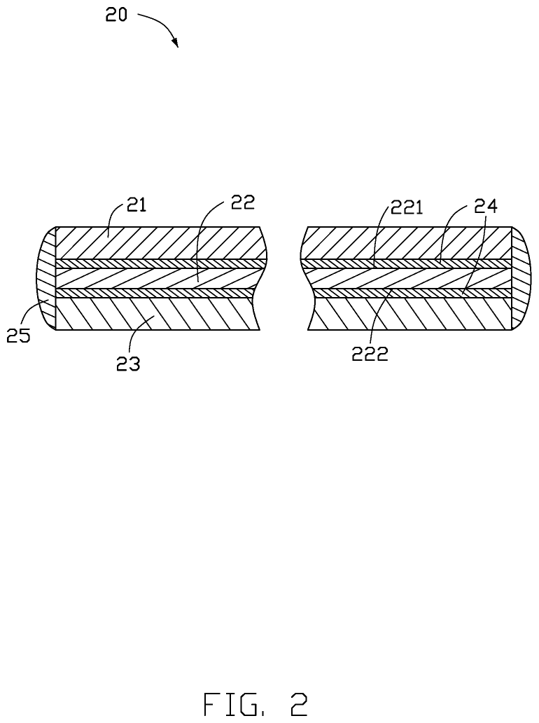

FIG. 2 shows a schematic structural diagram of a first embodiment of a display module 20. The display module 20 includes a display panel 21, an optical film set 22, a backplane 23, two first bonding members 24, and a second bonding member 25.

The display panel 21, the optical film set 22, and the backplane 23 are stacked in sequence. One first bonding member 24 is disposed between the display panel 21 and the optical film set 22, and a second first bonding member 24 is disposed between the optical film set 22 and the backplane 23 to bond the display panel 21, the optical film set 22, and the backplane 23 together. The second bonding member 25 is disposed on a peripheral side of the display panel 21, the optical film set 22, and the backplane 23. The second bonding member 25 enhances a bonded connection of the display panel 21, the optical film set 22, and the backplane 23 and is configured to prevent light leakage. The second bonding member 25 is an outer side surface of the display module 20 and protects the side of the display module 20.

The display panel 21 is substantially rectangular plate-shaped. The optical film set 22 is substantially the same size as the display panel 21 and includes a first adhering surface 221 facing the display panel 21 and a second adhering surface 222 facing the backplane 23. A size of the backplane 23 is substantially the same as a size of the display panel 21. The two first bonding members 24 are respectively uniformly applied on the first adhering surface 221 and the second adhering surface 222. The second bonding member 25 is applied to the peripheral sides of the display panel 21, the optical film set 22, and the backplane 23. In one embodiment, the display panel 21 is a liquid crystal display panel, and a surface of the display panel 21 is provided with a cover glass. The optical film set 22 may be a plurality, such that the plurality of optical film sets 22 are stacked, and every two adjacent optical film sets 22 are bonded together by a first bonding member 24.

The first bonding members 24 may be a translucent optical adhesive or a double-sided adhesive tape. Specifically, the first bonding members 24 may be foam tape, ultraviolet glue, or hot melt adhesive. In addition, the first bonding members 24 may be other kinds of optical adhesives having light transmitting properties according to actual needs.

The second bonding member 25 is made of a non-transparent material. In one embodiment, the second bonding member 25 is silica gel. In other embodiments, the second bonding member 25 can be made of other kinds of light non-transmitting materials that do not have translucency.

In assembly, the backplane 23 is placed on a positioning carrier, and a dispensing device uniformly applies one first bonding member 24 on the backplane 23. Then, the optical film set 22 is stacked on the backplane 23, the other first bonding member 24 is uniformly applied on the first adhering surface 221, and the display panel 21 is stacked on the first adhering surface 221, so that the backplane 23, the optical film set 22, and the display panel 21 are bonded together. Then, a dispensing device applies the second bonding member 25 to the peripheral side of the display panel 21, the optical film set 22, and the backplane 23.

It should be understood that the dispensing device is selected according to characteristics (viscosity, curing mode) of the bonding members and process parameters (dispensing accuracy, shape, and size) and the like. The dispensing device may be a mechanical arm, a three-axis platform, or a hand-held device.

The display module 20 bonds the display panel 21, the optical film set 22, and the backplane 23 together through the first bonding members 24 having light transmissibility and the second bonding member 25 made of non-transparent material. The second bonding member 25 improves a bonding connection of the display panel 21, the optical film set 22, and the backplane 23. The second bonding member 25 is an outer side surface of the display module 20 and prevents light leakage and protects the side of the display module 20. The display module 20 requires no bezel, which not only saves manufacturing costs, but also reduces thickness of the display module 20.

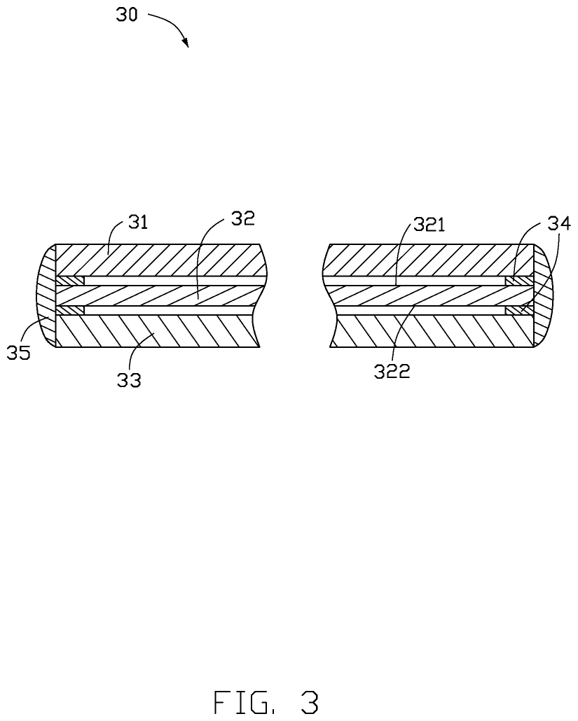

FIG. 3 shows a schematic structural diagram of a second embodiment of a display module 30. The display module 30 includes a display panel 31, an optical film set 32, a backplane 33, two first bonding members 34, and a second bonding member 35. The optical film set 32 includes a first adhering surface 321 facing the display panel 31 and a second adhering surface 322 facing the backplane 33. A difference between the second embodiment and the first embodiment is that the first bonding members 34 are respectively applied to an edge portion of the first adhesive surface 321 and the second adhesive surface 322 to bond the display panel 31 and the backplane 33.

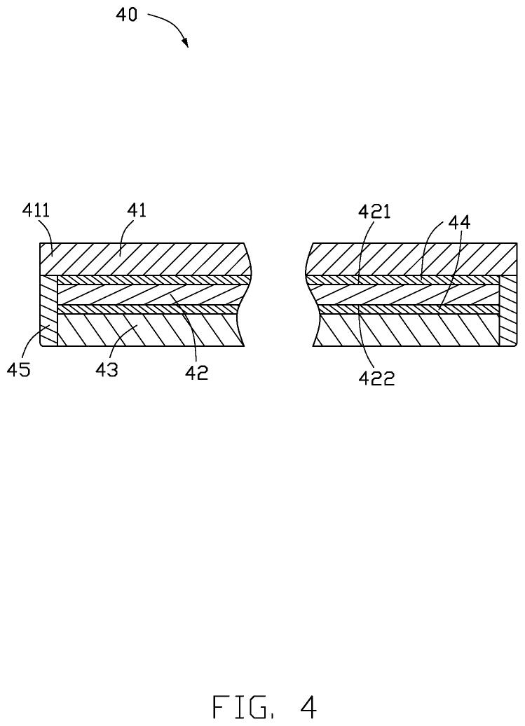

FIG. 4 shows a schematic structural diagram of a third embodiment of a display module 40. The display module 40 includes a display panel 41, an optical film set 42, a backplane 43, two first bonding members 44, and a second bonding member 45. The optical film set 42 includes a first adhering surface 421 facing the display panel 41 and a second adhering surface 422 facing the backplane 43. A difference between the third embodiment and the first embodiment is that the display panel 41 includes a first extending portion 411 extending beyond an edge of the optical film set 42 and the backplane 43, so that the second bonding member 45 is applied to the peripheral side of the optical film set 42 and the backplane 43 and bonded to the first extending portion 411.

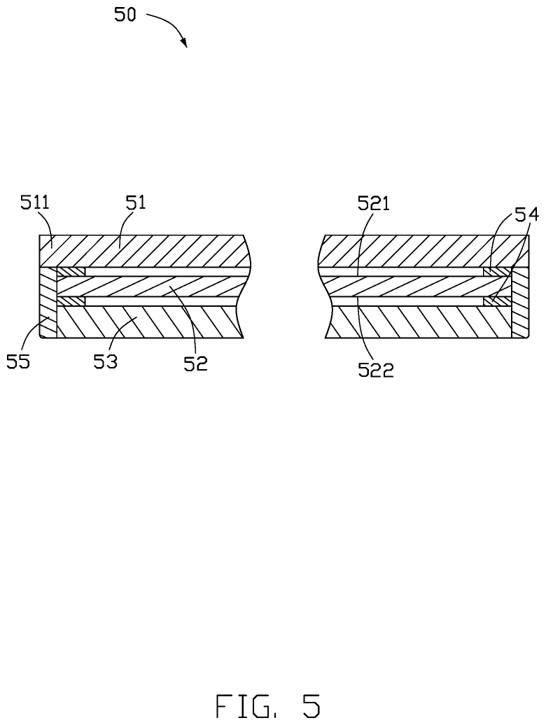

FIG. 5 shows a schematic structural diagram of a fourth embodiment of a display module 50. The display module 40 includes a display panel 51, an optical film set 52, a backplane 53, two first bonding members 54, and a second bonding member 55. The optical film set 52 includes a first adhering surface 521 facing the display panel 51 and a second adhering surface 522 facing the backplane 53. The fourth embodiment includes features of the second embodiment (shown in FIG. 3) and the third embodiment (shown in FIG. 4). That is, the display panel 51 includes a first extending portion 511 extending beyond an edge of the optical film set 52 and the backplane 53, the first bonding members 54 are respectively applied to an edge portion of the first adhesive surface 521 and the second adhesive surface 522 to achieve a bonded connection of the display panel 51, the optical film set 52, and the backplane 53, and the second bonding member 55 is applied to the peripheral side of the optical film set 42 and the backplane 43 and bonded to the first extending portion 411.

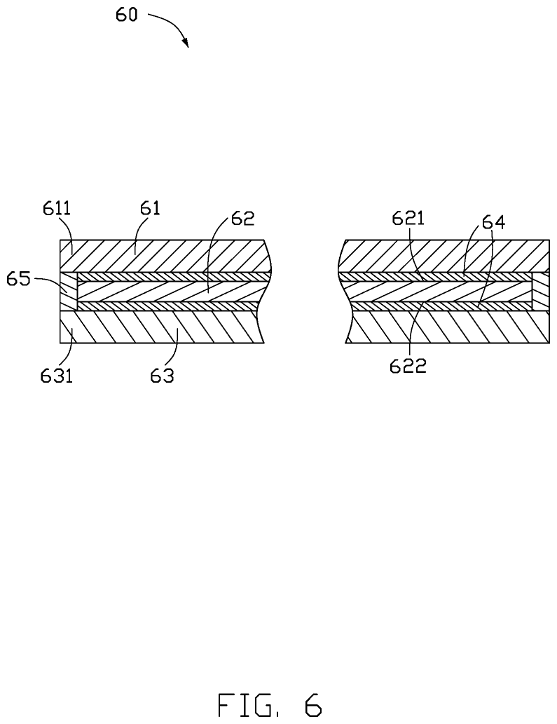

FIG. 6 shows a schematic structural diagram of a fifth embodiment of a display module 60. The display module 60 includes a display panel 61, an optical film set 62, a backplane 63, two first bonding members 64, and a second bonding member 65. The optical film set 62 includes a first adhering surface 621 facing the display panel 61 and a second adhering surface 622 facing the backplane 63. The display panel 61 includes a first extending portion 611 extending beyond an edge of the optical film set 62, and the backplane 63 includes a second extending portion 631 extending beyond the edge of the optical film set 62. The first bonding members are respectively applied uniformly on the first adhering surface 621 and the second adhering surface 622, and the second bonding member 65 is applied to a peripheral side of the optical film set 62 and bonded to the first extending portion 611 and the second extending portion 631.

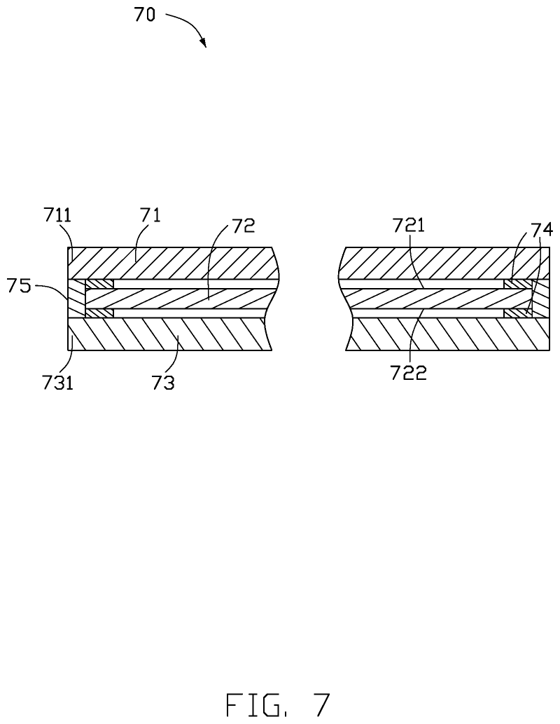

FIG. 7 shows a schematic structural diagram of a sixth embodiment of a display module 70. The display module 70 includes a display panel 71, an optical film set 72, a backplane 73, two first bonding members 74, and a second bonding member 75. The optical film set 72 includes a first adhering surface 721 facing the display panel 71 and a second adhering surface 722 facing the backplane 73. The display panel 71 includes a first extending portion 711 extending beyond an edge of the optical film set 72, and the backplane 73 includes a second extending portion 731 extending beyond the edge of the optical film set 72. The display module 70 is similar to the display module 60 (shown in FIG. 6), except that the first bonding members 74 are respectively applied to an edge portion of the first adhering surface 721 and the second adhering surface 722.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including, the full extent established by the broad general meaning of the terms used in the claims.

What is claimed is:

1. A display module comprising:
a display panel;
an optical film set;
a backplane;
at least two first bonding members bonding the display panel, the optical film set, and the backplane together; and
a second bonding member; wherein:
the optical film set is stacked between the display panel and the backplane;
the first bonding members are made of light-transmitting material, one first bonding member is disposed between the display panel and the optical film set, and a second first bonding member is disposed between the optical film set and the backplane;
the second bonding member is made of light non-transmitting material and is disposed on an outer side of at least one of the display panel, the optical film set, and the backplane.

2. The display module of claim 1, wherein:
the first bonding members are foam tape, ultraviolet glue, or hot melt adhesive.

3. The display module of claim 1, wherein:
the second bonding member is silica gel.

4. The display module of claim 1, wherein:
the optical film set comprises a first adhering surface facing the display panel and a second adhering surface facing the backplane;
the display panel, the optical film set, and the backplane have a same size;
the first bonding members are respectively applied uniformly on the first adhering surface and the second adhering surface;
the second bonding member is applied on peripheral sides of the display panel, the optical film set, and the backplane.

5. The display module of claim 1, wherein:
the optical film set comprises a first adhering surface facing the display panel and a second adhering surface facing the backplane;
the display panel, the optical film set, and the backplane have a same size;
the first bonding members are respectively applied on an edge portion of the first adhering surface and the second adhering surface;
the second bonding member is applied on a peripheral side of the display panel, the optical film set, and the backplane.

6. The display module of claim 1, wherein:
the optical film set comprises a first adhering surface facing the display panel and a second adhering surface facing the backplane;
the optical film set and the backplane have a same size;
the display panel comprises a first extending portion extending beyond an edge of the optical film set and the backplane;
the first bonding members are respectively applied uniformly on the first adhering surface and the second adhering surface;
the second bonding member is applied on a peripheral side of the optical film set and the backplane and bonded to the first extending portion.

7. The display module of claim 1, wherein:
the optical film set comprises a first adhering surface facing the display panel and a second adhering surface facing the backplane;
the optical film set and the backplane have a same size;
the display panel comprises a first extending portion extending beyond an edge of the optical film set and the backplane;
the first bonding members are respectively applied on an edge portion of the first adhering surface and the second adhering surface;
the second bonding member is applied on a peripheral side of the optical film set and the backplane and is bonded to the first extending portion.

8. The display module of claim 1, wherein:
the optical film set comprises a first adhering surface facing the display panel and a second adhering surface facing the backplane;
the display panel comprises a first extending portion extending beyond an edge of the optical film set;
the backplane comprises a second extending portion extending beyond the edge of the optical film set;
the first bonding members are respectively applied uniformly on the first adhering surface and the second adhering surface;
the second bonding member is applied on a peripheral side of the optical film set and is bonded to the first extending portion and the second extending portion.

9. The display module of claim 1, wherein:
the optical film set comprises a first adhering surface facing the display panel and a second adhering surface facing the backplane;
the display panel comprises a first extending portion extending beyond an edge of the optical film set;
the backplane comprises a second extending portion extending beyond the edge of the optical film set;
the first bonding members are respectively applied on an edge portion of the first adhering surface and the second adhering surface;
the second bonding member is applied on a peripheral side of the optical film set and is bonded to the first extending portion and the second extending portion.

10. A display device comprising:
a support stand; and
a display module mounted on the support stand, the display module comprising:
a display panel;
an optical film set;
a backplane;
at least two first bonding members bonding the display panel, the optical film set, and the backplane together; and
a second bonding member; wherein:
the optical film set is stacked between the display panel and the backplane;
the first bonding members are made of light-transmitting material, one first bonding member is disposed between the display panel and the optical film set, and a second first bonding member is disposed between the optical film set and the backplane;
the second bonding member is made of light non-transmitting material and is disposed on an outer side of at least one of the display panel, the optical film set, and the backplane.

11. The display module of claim 10, wherein:
the first bonding members are foam tape, ultraviolet glue, or hot melt adhesive.

12. The display module of claim 10, wherein:
the second bonding member is silica gel.

13. The display module of claim 10, wherein:
the optical film set comprises a first adhering surface facing the display panel and a second adhering surface facing the backplane;
the display panel, the optical film set, and the backplane have a same size;
the first bonding members are respectively applied uniformly on the first adhering surface and the second adhering surface;
the second bonding member is applied on peripheral sides of the display panel, the optical film set, and the backplane.

14. The display module of claim 10, wherein:
the optical film set comprises a first adhering surface facing the display panel and a second adhering surface facing the backplane;
the display panel, the optical film set, and the backplane have a same size;
the first bonding members are respectively applied on an edge portion of the first adhering surface and the second adhering surface;
the second bonding member is applied on a peripheral side of the display panel, the optical film set, and the backplane.

15. The display module of claim 10, wherein:
the optical film set comprises a first adhering surface facing the display panel and a second adhering surface facing the backplane;
the optical film set and the backplane have a same size;
the display panel comprises a first extending portion extending beyond an edge of the optical film set and the backplane;
the first bonding members are respectively applied uniformly on the first adhering surface and the second adhering surface;
the second bonding member is applied on a peripheral side of the optical film set and the backplane and bonded to the first extending portion.

16. The display module of claim 10, wherein:
the optical film set comprises a first adhering surface facing the display panel and a second adhering surface facing the backplane;
the optical film set and the backplane have a same size;
the display panel comprises a first extending portion extending beyond an edge of the optical film set and the backplane;
the first bonding members are respectively applied on an edge portion of the first adhering surface and the second adhering surface;
the second bonding member is applied on a peripheral side of the optical film set and the backplane and is bonded to the first extending portion.

17. The display module of claim 10, wherein:
the optical film set comprises a first adhering surface facing the display panel and a second adhering surface facing the backplane;
the display panel comprises a first extending portion extending beyond an edge of the optical film set;
the backplane comprises a second extending portion extending beyond the edge of the optical film set;
the first bonding member is applied uniformly on the first adhering surface and the second adhering surface;
the second bonding members are respectively applied on a peripheral side of the optical film set and is bonded to the first extending portion and the second extending portion.

18. The display module of claim 10, wherein:
the optical film set comprises a first adhering surface facing the display panel and a second adhering surface facing the backplane;
the display panel comprises a first extending portion extending beyond an edge of the optical film set;
the backplane comprises a second extending portion extending beyond the edge of the optical film set;
the first bonding members are respectively applied on an edge portion of the first adhering surface and the second adhering surface;
the second bonding member is applied on a peripheral side of the optical film set and is bonded to the first extending portion and the second extending portion.
